(19) United States
(12) Patent Application Publication
(10) Pub. No.: US 2010/0259903 A1
(43) Pub. Date: Oct. 14, 2010

(54) Memory Stick

(76) Inventor: Faisal A. Rehman, Dallas, TX (US)

Correspondence Address: WILSON DANIEL SWAYZE, JR., 3804 CLEARWATER CT., PLANO, TX, 75025, US

(21) Appl. No.: 12/420,994

(22) Filed: Apr. 9, 2009

(51) Int. Cl. H05K 7/00; H01R 13/66

(52) U.S. Cl. 361/728; 439/620.21

(57) ABSTRACT

A memory stick for a USB connection to a computer may include a USB connection portion for the connection to the computer and a cap portion to cover the USB connection portion. The cap portion and the USB connection portion may form a logo, and the USB connection portion may include a electronic circuit. The electronic circuit may be enclosed by a metal casing, and the USB connection portion may include a front section. A memory stick for a USB connection to a computer may include A USB connection portion for the connection to the computer and a cap portion to cover the USB connection portion. The USB connection portion may form a mascot.

### FIELD OF THE INVENTION

The present invention relates a memory stick and more particularly, to a logo memory stick including a USB connector that forms a logo or mascot for an institution such as a school or sports organization.

### BACKGROUND OF THE INVENTION

A conventional memory stick having a USB (Universal Serial Bus) port essentially comprises a bottom cover shell, a top cover shell covering the bottom cover shell, a circuit board mounted in between the bottom cover shell and the top cover shell, and a plastic covering molded on the top and bottom cover shells.

### SUMMARY

A memory stick for a USB connection to a computer may include a USB connection portion for the connection to the computer and a cap portion to cover the USB connection portion.

The cap portion and the USB connection portion may form a logo, and the USB connection portion may include a electronic circuit.

The electronic circuit may be enclosed by a metal casing, and the USB connection portion may include a front section.

A memory stick for a USB connection to a computer may include A USB connection portion for the connection to the computer and a cap portion to cover the USB connection portion. The USB connection portion may form a mascot.

### BRIEF DESCRIPTION OF THE DRAWINGS

The invention may be understood by reference to the following description taken in conjunction with the accompanying drawings, in which, like reference numerals identify like elements, and in which:

FIG. 1 illustrates a first logo memory stick of the present invention;

FIG. 2 illustrates the electronic circuits of the memory stick of the present invention;

FIG. 3 illustrates the logo cap portion and the logo USB connection portion;

FIG. 4 illustrates an exploded view of the logo cap portion;

FIG. 5 illustrates the second logo memory stick of the present invention;

FIG. 6 illustrates the logo cap portion and the logo USB connection portion of the second logo memory stick;

FIG. 7 illustrates the third logo memory stick of the present invention;

FIG. 8 illustrates the logo cap portion and the logo USB connection portion of the third logo memory stick.

### DETAILED DESCRIPTION

The present invention may include the memory stick which may include memory stick insertion in all school, colleges, universities and corporate logo and mascots.

The flexibility of memory stick insertion any where or any side of the logo as long as when joined together it will make a complete logo or mascots.

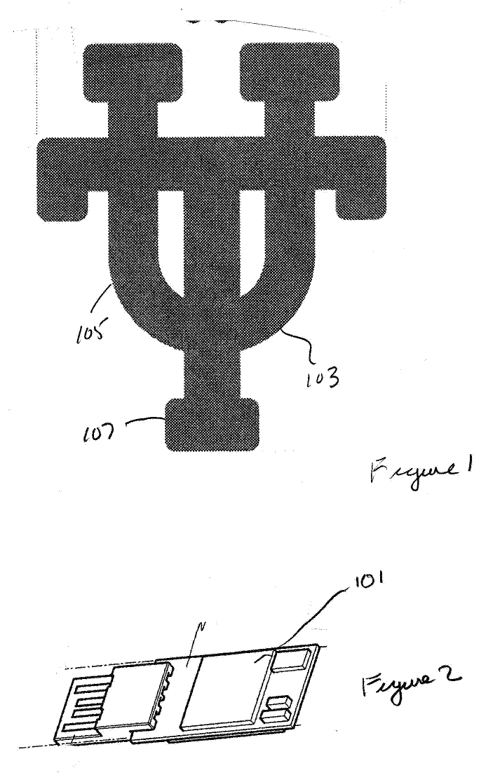

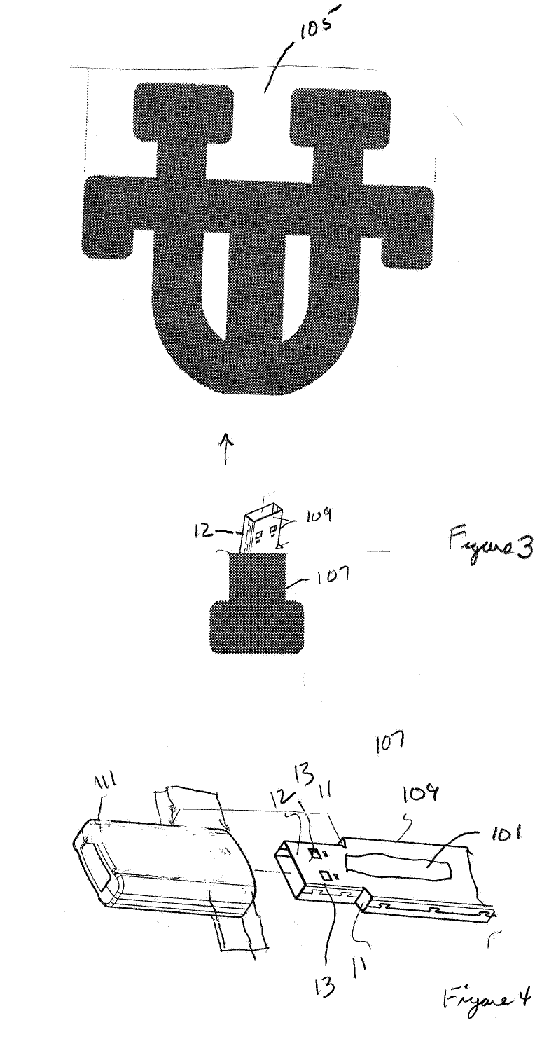

FIG. 1 illustrates a logo memory stick 103 which may in the form of a logo, a mascot, or other type of character in which an organization has adopted for identification of that organization. The teachings of the present invention apply equally to sports teams, schools, colleges, universities and businesses/corporations. The teachings of the present invention can be extended to groups of letters, mascots, animal shapes, characters such as animated characters and other types of objects that may be associated with an organization. While the present invention refers to a memory stick, the teachings of the present invention are equally applicable to a flash drive for a computer such as a personal computer, laptop, PDA, Blackberry, Smart phone or any such device. The logo memory stick 103 may include a logo cap portion 105 and a logo USB connector portion 107. The logo cap portion 105 may be used as a handle and may protect a portion of the electronics of the logo USB connector portion 107. The logo USB connector portion 107 may include electronic circuits 101 as illustrated in FIG. 2. The logo USB connector portion 107 may include a metal casing 109 to provide a protective covering for electronic circuits 101 and may include two shoulders 11 symmetrically disposed at two opposite lateral sides thereof, a front extension 12 forwardly extended from the front end between the shoulders 11 for insertion into a USB socket of a computer, and two eyelet lugs 13. The logo USB connector portion 107 may include a hollow plastic shell 111 which may be formed into a shape that cooperates with the logo being represented by the logo memory stick 103.

FIG. 1 illustrates a logo memory stick 103 which includes a logo cap portion 105 which may cover the front extension 12 of the metal casing 109 and may include a logo USB connector portion 107. The logo cap portion 105 and the logo USB connector portion 107 illustrates the logo of the University of Texas which may be an U imposed on a T.

FIG. 3 illustrates that the logo cap portion 105 is detachably connected to the logo USB connector portion 507 so that the logo USB connector portion 107 may be inserted into a computer.

FIG. 9 illustrates a computer 900 which may include a USB port 902 which may cooperate with the logo USB connector portion 107 and which interconnect with the metal casing 109 so that the electronic circuits 101 are connected with the computer 900.

FIG. 10 illustrates that the logo USB connector portion 107 has been inserted into the USB port 902 and may be detachably connected to the USB port 902. The logo USB connector portion 107 may be removed from the USB port 902 and reconnected with the logo cap portion 105 as illustrated in FIG. 3.

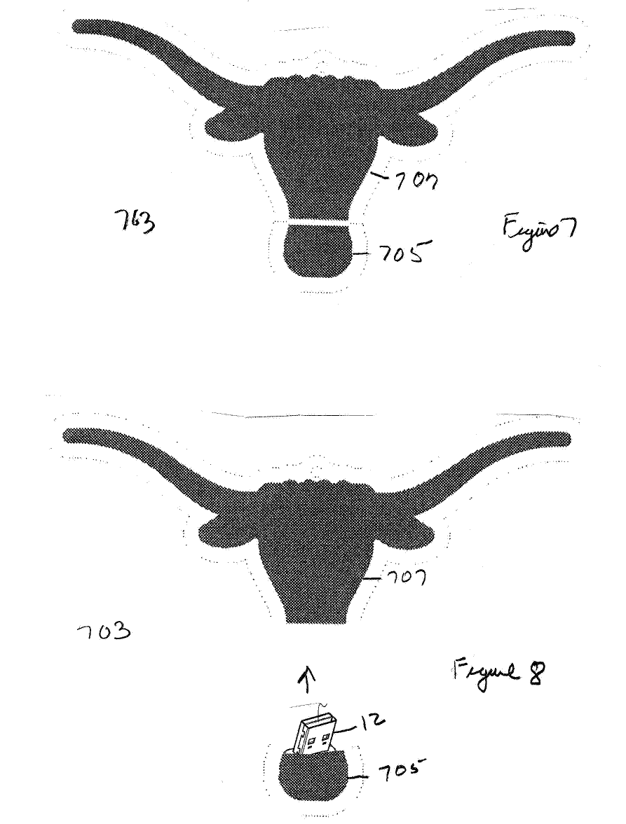

FIG. 5 illustrates a logo memory stick 503 which may be in the form of a logo, a mascot, or other type of character in which an organization has adopted for identification of that organization. The logo memory stick 503 may include a logo cap portion 505 and a logo USB connector portion 507.

The logo cap portion 505 may be used as a handle and may protect a portion of the electronics of the logo USB connector portion 107. FIG. 5 illustrates the logo USB connector portion 507 which may include a metal casing 109 to provide a protective covering for electronic circuits 101 and may include two shoulders 11 symmetrically disposed at two opposite lateral sides thereof, a front extension 12 forwardly extended from the front end between the shoulders 11 for insertion into a USB socket of a computer, and two eyelet lugs 13. The logo USB connector portion 507 may include a hollow plastic shell 111 which may be formed into a shape that cooperates with the logo being represented by the logo memory stick 503.

FIG. 5 illustrates a logo memory stick 503 which includes a logo cap portion 505 which may cover the front extension 12 of the metal casing 109 and may include a logo USB connector portion 507. The logo cap portion 505 and the logo USB connector portion 507 illustrates the logo of the University of Oklahoma which may be an U imposed on an O.

FIG. 6 illustrates that the logo cap portion 505 is detachably connected to the logo USB connector portion 507 so that the logo USB connector portion 507 may be inserted into a computer.

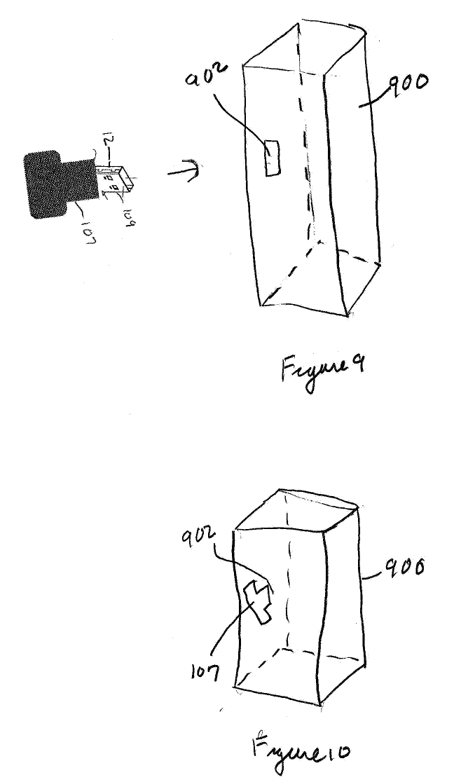

FIG. 7 illustrates a logo memory stick 703 which may be in the form of a logo, a mascot, or other type of character in which an organization has adopted for identification of that organization. The logo memory stick 703 may include a logo cap portion 705 and a logo USB connector portion 707. The logo cap portion 705 may be used as a handle and may protect a portion of the electronics of the logo USB connector portion 107. FIG. 7 illustrates that the logo cap portion 705 is detachably connected to the logo USB connector portion 707 so that the logo USB connector portion 707 may be inserted into a computer.

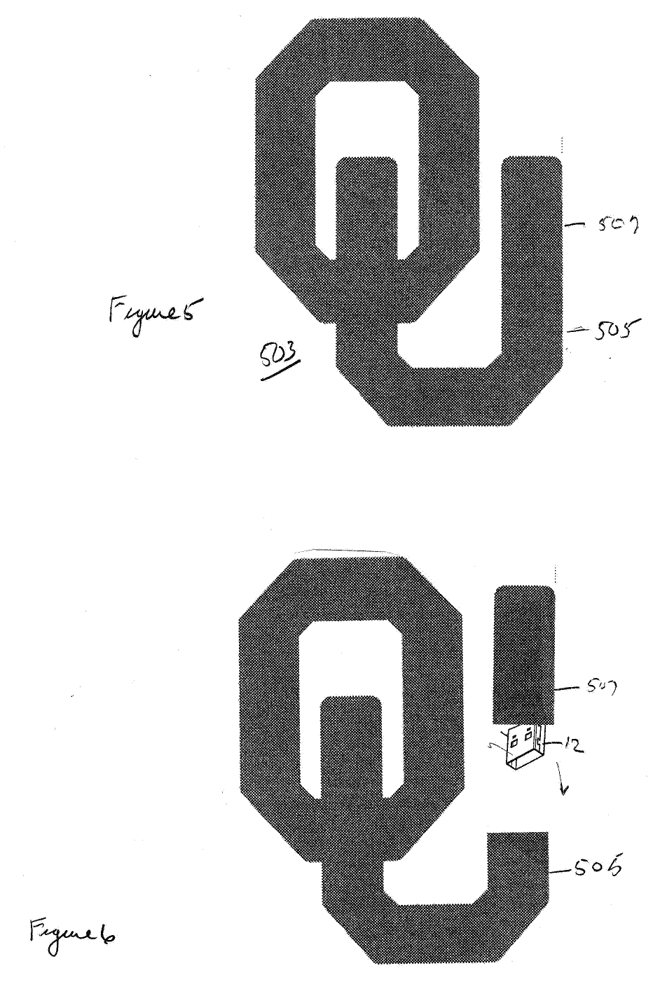

FIG. 8 illustrates the logo USB connector portion 707 which may include a metal casing 109 (FIG. 4) to provide a protective covering for electronic circuits 101 and may include two shoulders 11 symmetrically disposed at two opposite lateral sides thereof, a front extension 12 forwardly extended from the front end between the shoulders 11 for insertion into a USB socket of a computer, and two eyelet lugs 13. The logo USB connector portion 707 may include a hollow plastic shell 111 which may be formed into a shape that cooperates with the logo being represented by the logo memory stick 703.

FIG. 7 illustrates a logo memory stick 703 which includes a logo cap portion 705 which may cover the front extension 12 of the metal casing 109 and may include a logo USB connector portion 707. The logo cap portion 705 and the logo USB connector portion 707 illustrate the mascot which may be a Texas Longhorn.

FIG. 8 illustrates that the logo cap portion 705 is detachably connected to the logo USB connector portion 707 so that the logo USB connector portion 707 may be inserted into a computer.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed.

1) A memory stick for a USB connection to a computer, comprising:
a USB connection portion for the connection to the computer;
a cap portion to cover the USB connection portion;
wherein the cap portion and the USB connection portion form a logo.

2) A memory stick for a USB connection to a computer as in claim 1, wherein the USB connection portion includes a electronic circuit.

3) A memory stick for a USB connection to a computer as in claim 2, wherein the electronic circuit is enclosed by a metal casing.

4) A memory stick for a USB connection to a computer as in claim 1, wherein the USB connection portion includes a front section.

5) A memory stick for a USB connection to a computer, comprising:
a USB connection portion for the connection to the computer;
a cap portion to cover the USB connection portion;
wherein the cap portion and the USB connection portion form a mascot.

6) A memory stick for a USB connection to a computer as in claim 5, wherein the you USB connection portion includes a electronic circuit.

7) A memory stick for a USB connection to a computer as in claim 6, wherein the electronic circuit is enclosed by a metal casing.

8) A memory stick for a USB connection to a computer as in claim 5, wherein the USB connection portion includes a front section.
